(19) United States
(12) Patent Application Publication
(10) Pub. No.: US 2011/0250734 A1
(43) Pub. Date: Oct. 13, 2011

(54) SPECIMEN PROCESSING APPARATUS AND METHOD THEREOF

(75) Inventors: Seungho CHOI, Yongin-si (KR); Gwangseon Byun, Yongin-si (KR); Sunyoung Lee, Suwon-si (KR); Kyungwoo Lee, Hwaseong-si (KR); Eungoo Lee, Hwaseong-si (KR); Hongshik Kim, Yongin-si (KR)

(73) Assignee: Samsung Electronics Co., Ltd., Suwon-si (KR)

(21) Appl. No.: 13/083,985

(22) Filed: Apr. 11, 2011

(30) Foreign Application Priority Data
Apr. 12, 2010 (KR) 10-2010-0033433

(51) Int. Cl. H01L 21/02

(52) U.S. Cl. 438/463; 257/E21.002

(57) ABSTRACT

An apparatus and a method of processing a specimen includes a final analysis specimen that is manufactured by sequentially performing specimen processing processes using a laser beam with respect to an initial laminate specimen loaded on a stage. As a result, the final specimen manufacturing time may be reduced and the quality of the final specimen may be improved.

### CROSS-REFERENCE TO RELATED APPLICATIONS

This U.S, non-provisional patent application claims priority under 35 U.S.C. §119(a) from Korean Patent Application No. 10-2010-0033433, filed on Apr. 12, 2010, the entire contents of which are hereby incorporated by reference.

### BACKGROUND

1. Field of the Invention

The present disclosure herein relates to specimen processing apparatus and method thereof, and more particularly, to an apparatus and a method of processing a specimen to be analyzed using a transmission electron microscope (TEM).

2. Description of the Related Art

When a semiconductor device is manufactured, processes including a diffusion process, an oxidation process, a metal process, and so forth are repeatedly performed, accordingly depositing films of various materials, such as a metal film, a nitride film or an oxide film, on a substrate. Recently, the manufacturing process is getting complicated and scaled-down,

If a defect occurs in any of the plurality of films, abnormality consequently occurs in a semiconductor device manufactured by subsequent processes. To this end, it is necessary to cut out a specimen from a substrate under the semiconductor manufacturing process to determine a defect of a specific film using a TEM.

### SUMMARY

The present disclosure provides an apparatus and a method capable of processing an analysis specimen having a dimple shape by using a laser beam.

Additional features and utilities of the present general inventive concept will be set forth in part in the description which follows and, in part, will be obvious from the description, or may be learned by practice of the present general inventive concept.

Objects of the general inventive concept are not limited thereto. That is, other objects will be apparently understood from the following description by those skilled in the art.

Exemplary embodiments of the general inventive concept provide specimen processing apparatuses including a stage adapted to place a specimen thereon; and a laser unit disposed above the stage and adapted to laser-process the specimen,

In some exemplary embodiments, the specimen may include a preliminary specimen in intermediate processes for manufacturing of a final specimen which comprises a dimple, and the laser-processing may include cutting, grinding, dimpling, and milling of the preliminary specimen and uses a laser beam.

In other exemplary embodiments, the laser unit may include a power supply member; and a laser beam emitting member adapted to generate the laser beam using power supplied from the power supply member and emit the laser beam to the preliminary specimen, and the specimen processing apparatus may further include a controller adapted to control the power supply member to supply the laser beam emitting member with different powers according to the laser-processing.

In still other exemplary embodiments, the laser unit may further include an etching gas injecting member adapted to inject an etching gas to a laser beam emitted region of the preliminary specimen.

In even other exemplary embodiments, the laser beam emitting member may include an upper wall; a first sidewall annularly extending downward from a central part of a lower surface of the upper wall; a laser oscillator disposed at an inside of the first sidewall and adapted to generate the laser beam; an optical system disposed below the laser oscillator within the first sidewall and adapted to focus the laser beam and emit the focused laser beam to the preliminary specimen, and the etching gas injecting member may include a second sidewall annularly extending downward from a circumference of the upper wall; and a gas supply line adapted to supply the etching gas through a space formed between the first and second sidewalls.

In yet other exemplary embodiments, the specimen processing apparatus may further include a thickness measuring unit adapted to measure thickness of a bottom wall BW of the dimple being dimpled or milled by the laser unit.

In further exemplary embodiments, the thickness measuring unit may include a light emitting part adapted to emit a light to the bottom wall BW of the dimple; a light receiving part adapted to receive the light reflected from the bottom wall BW of the dimple; and an analyzing part adapted to receive a wavelength detection signal of the reflected light from the light receiving part and calculate the thickness of the bottom wall BW of the dimple varying in accordance with the wavelength of the reflected light.

In still further exemplary embodiments, the light may include a laser beam.

In even further exemplary embodiments, the specimen processing apparatus may further include a stage driver adapted to move the stage horizontally and/or vertically, and/or rotate the stage such that the stage is moved and/or rotated relative to the laser unit,

In other exemplary embodiments of the general inventive concept, specimen processing methods include (a) preparing a specimen by depositing a plurality of cut substrates; (b) cutting the specimen into a size appropriate for a sample analysis and grinding the cut specimen; (c) forming a dimple on the specimen; and (d) milling a bottom wall BW of the dimple, wherein the operations (b), (c), and (d) are performed by emitting a laser beam to the specimen.

In some exemplary embodiments, the operations (b), (c), and (d) may be performed while an etching gas is supplied to a laser beam emitted region of the specimen.

In other exemplary embodiments, the operations (b), (c), and (d) may be performed while the specimen is moved relative to a position emitting the laser beam.

In still other exemplary embodiments, the operations (c) and (d) may be performed while a thickness of the bottom wall BW of the dimple is measured by detecting a wavelength of a reflected light of a light emitted to the bottom wall BW of the dimple.

In even other exemplary embodiments, the light may include a laser beam.

In yet other exemplary embodiments, intensity of the laser beam used in the operation (d) may be smaller than intensity of the laser beam used in the operation (c).

In further exemplary embodiments, the operation (a) may include cutting a semiconductor substrate formed with patterns and a dummy substrate respectively into a rectangular shape by the laser beam; and depositing and bonding the cut dummy substrate to upper and lower parts of the cut semiconductor substrate,

In still further exemplary embodiments, the operation (b) may include firstly cutting the specimen in a deposition direction; secondly cutting the first-cut specimen into a disc shape; and grinding both sides of the second-cut specimen, wherein the first cutting, second cutting, and grinding are performed by emitting the laser beam to the specimen.

In yet another exemplary embodiment, a specimen processing apparatus to form a final specimen supported by a stage to be analyzed comprises a laser unit disposed above the stage to generate a laser beam to a surface of the specimen in response to a supplied power, and a control module to determine a specimen processing process to apply to the specimen and to control the laser unit based on the determined specimen processing process,

In still a further exemplary embodiment, a specimen processing method to form a final specimen supported by a stage to be analyzed comprises emitting a laser beam to a surface of the specimen in response to a supplied power, determining specimen processing processes to be applied to the specimen, and moving the specimen with respect to the laser beam based on the determined specimen processing process.

In another exemplary embodiment, a specimen processing method comprises forming an initial laminate specimen including a substrate layer and a dummy layer, emitting a laser beam to the initial laminate specimen, and moving the specimen with respect to the laser beam based on a sequence of specimen process procedures to form a finalized specimen to be analyzed.

### BRIEF DESCRIPTION OF THE DRAWINGS

The accompanying drawings are included to provide a further understanding of the general inventive concept, and are incorporated in and constitute a part of this specification. The drawings illustrate exemplary embodiments of the general inventive concept and, together with the description, serve to explain principles of the general inventive concept. In the drawings:

The above and/or other features of the present general inventive concept will become apparent and more readily appreciated from the following description of the exemplary embodiments, taken in conjunction with the accompanying drawings, in which:

FIGS. 1A through 1G are views showing a shape of a specimen according to the progress of specimen processing processes;

FIG. 2 is a view of a specimen processing apparatus according to an embodiment of the general inventive concept;

FIG. 3 is an enlarged view of a laser unit shown in FIG. 2;

FIG, 4 shows a slicing process of a laminate specimen;

FIG. 5 shows a punching process of the sliced specimen;

FIG. 6 shows a grinding process of the punched specimen;

FIG. 7 shows a dimpling process of the ground specimen;

FIG. 8A is a cross sectional view of the dimpled specimen;

FIG. 8B is a cross sectional view of a final specimen for analysis;

FIG. 9 is a flowchart illustrating an exemplary specimen processing method according to the present general inventive concept; and

FIG. 10 is a flowchart illustrating an exemplary method of forming a specimen to be analyzed according to the present general inventive concept

### DETAILED DESCRIPTION OF THE EMBODIMENTS

Reference will now be made in detail to the exemplary embodiments of the present general inventive concept, examples of which are illustrated in the accompanying drawings, wherein like reference numerals refer to the like elements throughout. The exemplary embodiments are described below in order to explain the present general inventive concept by referring to the figures.

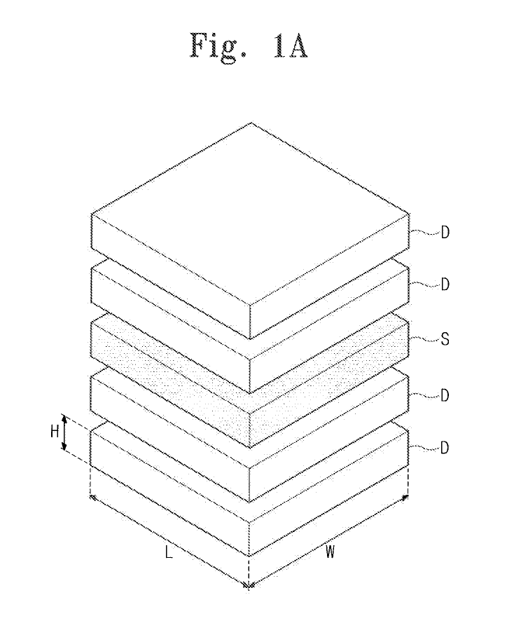

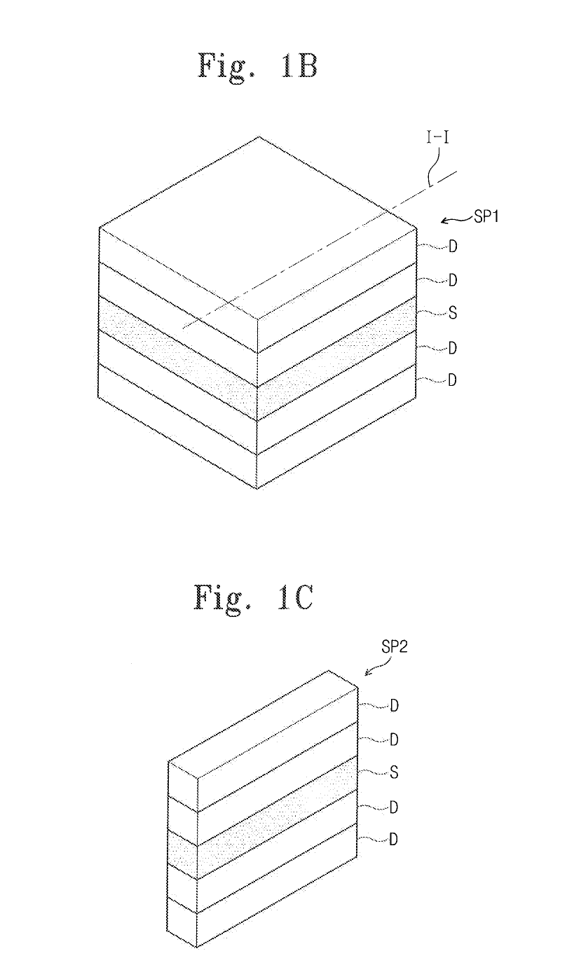

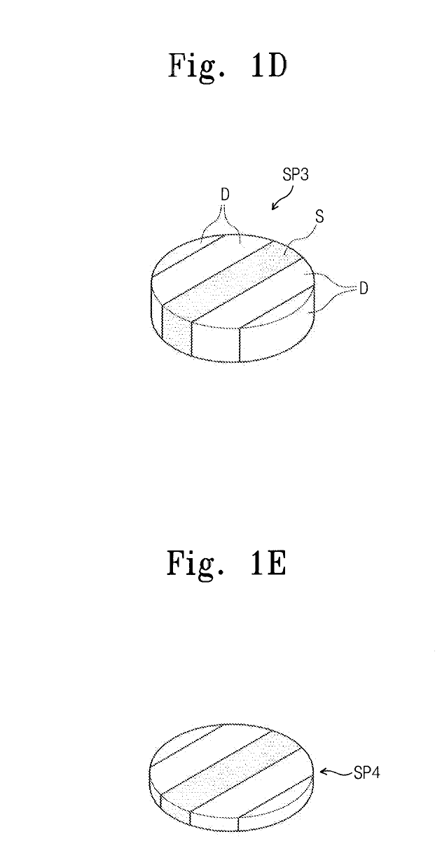

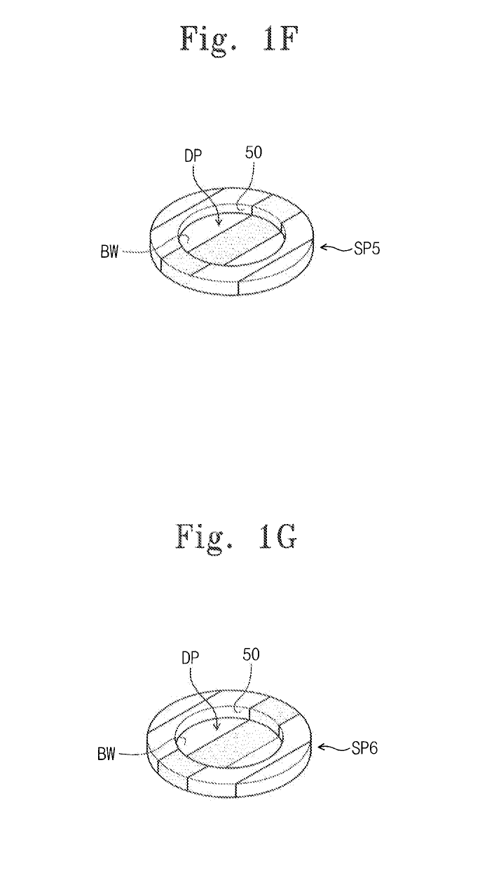

FIG. 1A through FIG. 1G are views showing shapes of a specimen according to the progress of specimen processing processes.

The specimen processing processes may include cutting, bonding, slicing, punching, grinding, dimpling, and milling. Further, any of the above-mentioned specimen processes may be sequentially performed, A laser beam may be used to process the specimen in all the processes except the bonding. When the laser beam is emitted to the specimen, a surface temperature of the specimen quickly increases, thereby melting and evaporating part of the specimen around the surface. Constituent elements of the specimen are thus removed and accordingly the specimen processing processes are performed.

Referring to FIG. 1A, a cut semiconductor substrate S and a cut dummy substrate D having sizes according to a predetermined height (H), length (L) and width (W) are prepared through the cutting. More specifically, a semiconductor substrate formed with patterns to be analyzed is prepared and cut into a size of about 4 mm×5 mm by a laser beam. Next, a dummy substrate is separately prepared and cut by a laser beam to have the substantially same area as the cut semiconductor substrate S. For example, a single cut semiconductor substrate S may be provided while four cut dummy substrates D are provided. However, a plurality of the cut semiconductor substrate S may be provided to perform the analysis at several points.

Referring to FIG. 1B, a laminate specimen SP1 constituted by the cut semiconductor substrate S and the cut dummy substrates D is prepared through the bonding process. More specifically, two cut dummy substrates D are deposited respectively on upper and lower parts, respectively, of the cut semiconductor substrate S. The substrate S and the dummy substrates D are bonded in the deposited state using a bonding resin, such as a G1-epoxy resin. Next, the cut semiconductor substrate S and the cut dummy substrates D are compressed together so that the G1-epoxy resin is evenly and thinly spread among the cut semiconductor substrate S and the dummy substrates D. The substrate S and the dummy substrates D are then heated at a high temperature to form the laminate specimen SP1.

Referring to FIG. 1C, the laminate specimen SP1 is formed into a sliced specimen SP2 through the slicing process. More specifically, the sliced specimen SP2 is formed by slicing the laminate specimen SP1 along line I-I shown in FIG. 1B using a laser beam. A laser unit to generate a laser beam is described in greater detail below. Accordingly, sliced specimen SP2 is formed taking the shape of a plate. The sliced specimen SP2 may have a thickness of about 0.5 mm to 1 mm.

Referring to FIG. 1D, the sliced specimen SP2 is formed into a punched specimen SP3 through the punching process. The punched specimen S3 is formed by cutting the sliced specimen SP2 into a disc shape having about a 3 mm diameter using a laser beam.

Referring to FIG. 1E, the punched specimen SP3 is formed into a ground specimen SP4 through the grinding process. The ground specimen SP4 is formed by grinding both sides of the punched specimen SP3 using a laser beam. The sides of the punched specimen SP3 may be grinded to a thickness of about 10 μm or less.

Referring to FIG. 1F, the ground specimen SP4 is formed into a dimpled specimen SP5 through the dimpling process. The dimpled specimen SP5 is formed by forming a dimple (DP) on one surface of the ground specimen SP4 that is surrounded by an inner circumferential wall 50. The surface of the ground specimen SP4 may be formed to a thickness of about 1 □ or less. In at least one exemplary embodiment shown in FIG. 1F, the dimple is formed as a rough basic shape rather than being precisely formed,

Referring now to FIG. 1G, the dimpled specimen SP5 is formed into a final specimen SP6 to be analyzed through the milling process. The final analysis specimen SP6 is formed by milling a bottom wall BW of the dimple DP using a laser beam. Since the milling procedure executes a precise surface processing to remove thin and fine scratches from the bottom wall BW of the dimple DP, intensity of the laser beam may be smaller than intensity of the laser beam for the dimpling.

The final analysis specimen SP6 thus manufactured through the above processes is fixed by a specimen holder (not shown) and placed on a specimen stage (not shown) of a transmission electron microscope (TEM). Electron beams accelerated through a high potential difference are incident to and transmitted through the bottom wall BW of the dimple DP to analyze the final specimen SP6. Accordingly, an image is obtained from the transmitted electron beams, and a crystal structure of the image is analyzed through a diffraction pattern obtained from diffracted electron beams.

Hereinafter, a specimen processing apparatus to perform the above specimen processing processes will be described.

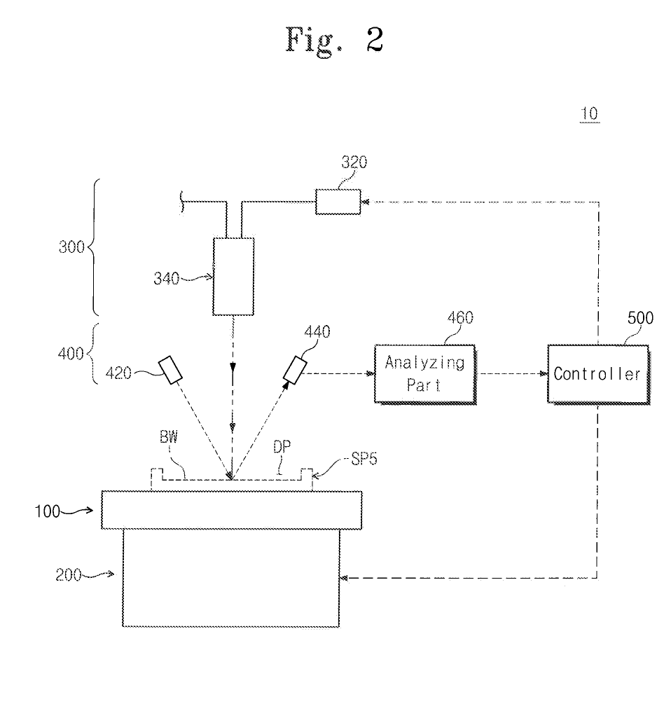

FIG. 2 shows a specimen processing apparatus according to an embodiment of the general inventive concept.

Referring to FIG. 2, the specimen processing apparatus 10 includes a stage 100, a stage driver 200, a laser unit 300, a thickness measuring unit 400, and a controller 500.

The laminate specimen SP1 is loaded to the stage 100. On the stage 100, the laminate specimen SP1 is processed into the final analysis specimen SP6 sequentially through the slicing, punching, grinding, dimpling and milling process discussed in detail above. For convenience, the dimpled specimen SP5 having undergone the dimpling process is illustrated in FIG. 2.

The stage driver 200 may linearly move the stage 100 in vertical and/or horizontal directions relative to the laser unit 300. The stage drive 200 may also rotate the stage 100 about a vertical rotation axis thereof. Accordingly, the stage driver 200 may linearly move in vertical and horizontal directions or rotate the stage 100 such that the specimen is processed by the laser unit 300 to form the specimens SP1-SP6 described in detail above,

The laser unit 300 is fixed above the stage 100 and adapted to generate a laser beam LB to perform laser-processing of the specimen placed on the stage 100. As mentioned above, the laser-processing includes the cutting, slicing, punching, grinding, dimpling, and milling using the laser beam LB generated by the laser unit 300.

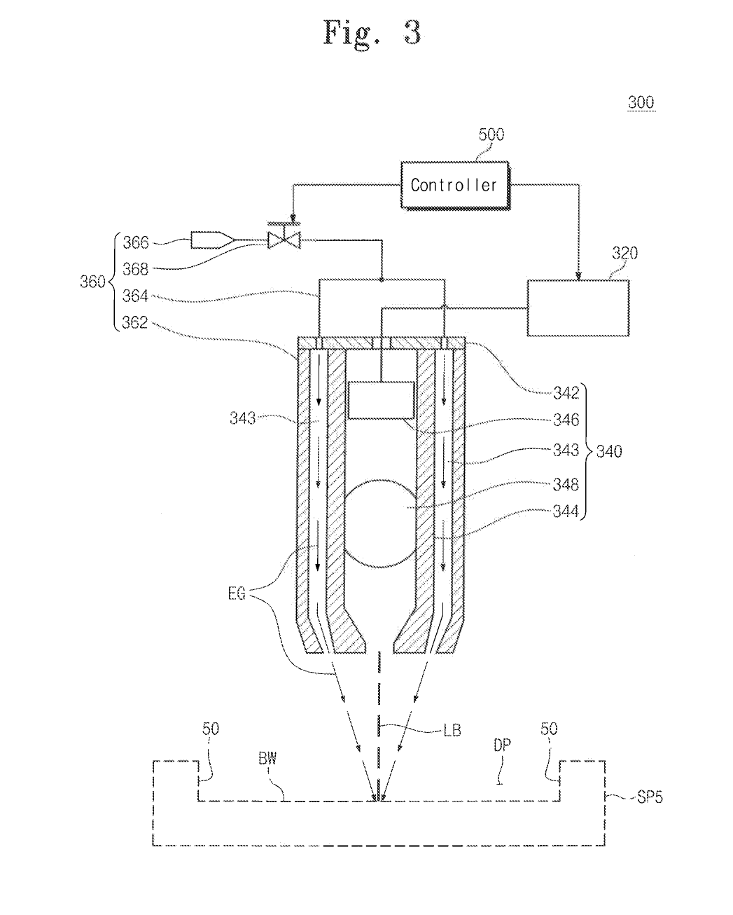

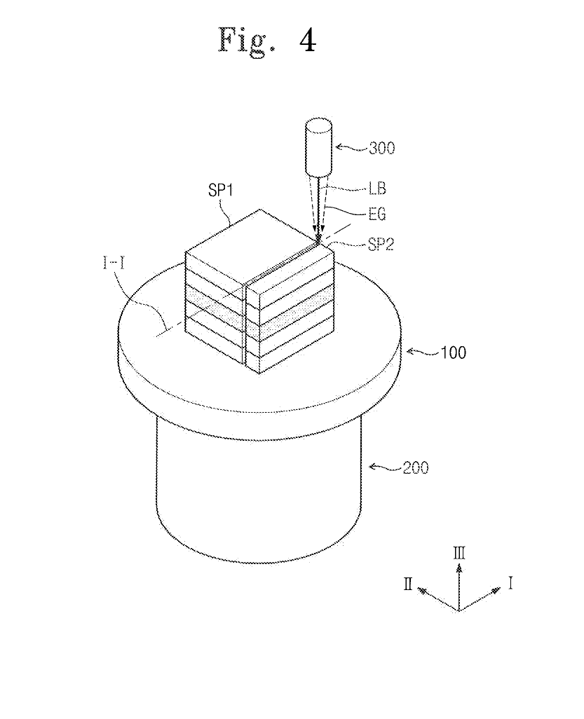

An enlarged view of the laser unit 300 is illustrated in FIG. 3. The laser unit 300 includes a power supply unit 320, a laser beam emitting member 340, and an etching gas injecting member 360.

The power supply member 320 supplies power to the laser beam emitting member 340. More specifically, the power supply member 320 may apply different powers according to particular process applied to the specimen For example, the power applied to the laser beam emitting member 340 may lower during the milling process, compared to the power supplied during the punching process.

The laser beam emitting member 340 generates a laser beam LB and emits the laser beam LB to the specimen. The laser beam emitting member 340 includes an upper wall 342, a first sidewall 344, a laser oscillator 346, and an optical system 348. The upper wall 342 may be in the form of a disc. The first sidewall 344 may annularly extend downward from a central part of a lower surface of the upper wall 342. The laser oscillator 346 is disposed at an inner upper part of the first sidewall 344 and generates the laser beam LB by using the power applied from the power supply member 320. The optical system 348 is disposed below the laser oscillator 346 within the first sidewall 344, and focuses the laser beam LB generated from the laser oscillator 346 toward to the specimen.

The etching gas injecting member 360 injects an etching gas EG to a laser beam emitted region of the specimen so as to accelerate the laser processing of the specimen. The etching gas EG injected by the etching gas injecting member may include, but is not limited to, CF₄, C₂F₆, C₃F₈ or C₂F₆. The etching gas injecting member 360 further includes a second sidewall 362 annularly extending downward from a circumference of the upper wall 342 of the laser beam emitting member 340 to define a gas channel 343 therebetween. The etching gas is supplied to the gas channel 343 between the first sidewall 344 and the second sidewall 362 through one side of a gas supply line 364 and injected to the laser beam emitted region of the specimen through an opened lower part of the gas channel 343 between the first and second sidewalls 344 and 362. A gas supply source 366 is connected to the other side of the gas supply line 364. A valve 368 is mounted on the gas supply line 364 and is operable in an open and closed position to control the flow of gas into the gas chamber 343. In addition, a controller 500 may control the power supply 320 and the valve 368 according to the specimen process applied to the specimen. The controller 500 is discussed in greater detail below.

Although at least one exemplary embodiment illustrated in FIG. 3 shows the etching gas injecting member 360 integrally formed with the laser beam emitting member 340, the etching gas injecting member 360 may be provided separately from the laser beam emitting member 340. For example, the etching gas injecting member 360 may include an injection nozzle and a gas supply member that supplies the etching gas to the injection nozzle. The injection nozzle may be disposed above the stage 100 (FIG. 2) to inject the etching gas to the specimen.

Referring again to FIG. 2, the thickness measuring unit 400 measures thickness of the bottom wall BW of the dimple DP of the specimen. the bottom wall BW being dimpled and/or milled by the laser unit 300, The thickness measuring unit 400 includes a light emitting part 420, a light receiving part 440, and an analyzing part 460. The light emitting part 420 is disposed at one upper side of the stage 100 to emit a light onto the bottom wall BW of the dimple DP of the specimen. The light emitted by the light emitting part 420 may include a laser beam. The light receiving part 440 is disposed at the other upper side of the stage 100 to receive the light reflected from the bottom wall BW of the dimple DP. The analyzing part 460 receives a wavelength detection signal of the reflected light from the light receiving part 440 and calculates the thickness of the bottom wall BW of the dimple DP varied in accordance with the wavelength of the reflected light. For example, the analyzing part 460 may include a memory (not shown), and may have a look-up table stored in the memory 460. The look-up table may include a list of light wavelengths each corresponding to a thickness. Accordingly, by detecting a wavelength of reflected light, the analyzing part 460 can determine a thickness of the bottom wall BW according to the look-up table.

The controller 500 controls the overall operations of the specimen processing apparatus 10. More specifically, the controller 500 may determine a specimen processing process applied to the specimen, and may control the stage driver 200 and the power supply member 320 of the laser unit 300 based on the determined specimen processing process. That is, the controller 500 may control the stage driver 200 to move or rotate the stage 100 relative to the laser unit 300, so that the specimen placed on the stage 100 can be processed by the laser unit 300 which is in the fixed position. For example, when the controller 500 determines that the punching process is to be applied to a specimen, the controller may control the stage driver 200 to rotate with respect to a laser beam emitted by the laser unit 300, such that that the punched specimen SP3 is formed. When the controller 500 determines that the grinding process is to be applied to a specimen, the control 500 may control the stage driver 200 to move horizontally with respect to the laser beam, such that the ground specimen SP4 is formed.

Additionally, the controller 500 may control the power supply member 320 of the laser beam 300 to adjust the intensity of the laser beam LB, and the gas ejecting member 360 to control an amount of etching gas EG injected to the specimen based on the specimen processing process. For example, when milling the specimen during the milling process, the intensity of the laser beam LB needs to be smaller than when the dimpling process is performed since the milling requires a precise surface processing. To this end, the controller 500 may control the power supply member 320 so that a lower power is applied to the laser oscillator 346 (FIG. 3), thereby reducing the intensity of the laser beam LB emitted from the laser unit 300. Furthermore, the bottom wall BW of the dimple DP needs to be processed to a thickness of about 1 □ or less during the dimpling. Therefore, the controller 500 may control the power supply member 320 to interrupt the power supply to the laser oscillator 346 when the thickness of the bottom wall BW of the dimple DP is measured to be about 1 μm by the thickness measuring unit 400.

Hereinafter, procedures of the laser-processing the specimens SP1, SP2, SP3, SP4, and SP5 shown in FIG. 1 using the above-structured specimen processing apparatus 10 will be described.

FIG. 4 illustrates the slicing process, which forms the laminate specimen SP1. Referring to FIG. 4, the laminate specimen SP1 is loaded on the stage 100. The laminate specimen SP1 is aligned in a first direction I and a second direction II according to rotation of the stage 100 and moved to an initial process position by the horizontal movement of the stage 100. The laser unit 300 emits the laser beam LB vertically downward to the laminate specimen SP1. The laminate specimen SP1 is linearly moved in the first direction I according to the movement of the stage 100. At this time, the laminate specimen SP1 is sliced in the first direction I along line I-I by the laser beam LB emitted by the laser unit 300 to form a sliced specimen SP2. The sliced specimen SP2 may have a thickness of about 0.5 to 1 mm, In addition, the laser unit 300 may inject the etching gas EG to the laser beam emitted region of the laminate specimen SP1 to accelerate the processing using the laser beam LB.

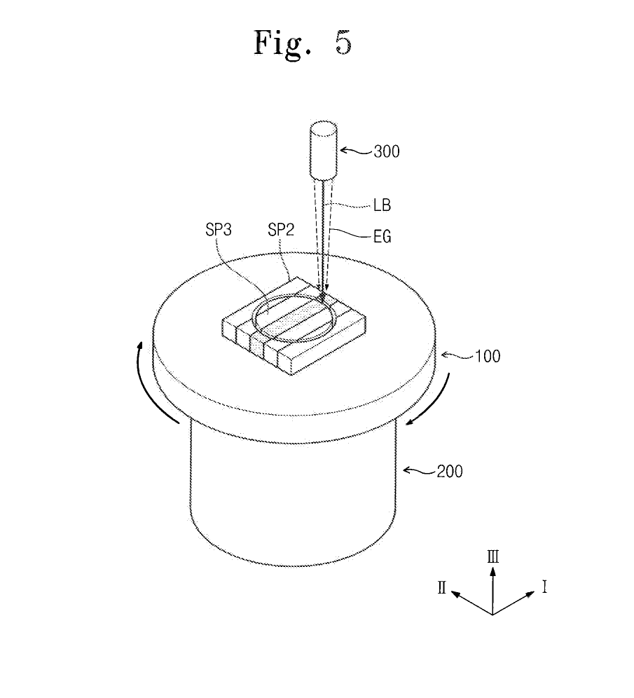

FIG. 5 shows the punching process of the sliced specimen SP2. Referring to FIG. 5, the sliced specimen SP2 is disposed on the stage 100 by an operator or a robot (not shown) such that the laminated surface thereof faces the stage 100. The sliced specimen SP2 is moved to the initial processing position by the horizontal movement of the stage 100. The laser unit 300 emits the laser beam LB vertically downward to the sliced specimen SP2. As the laser beam LB is emitted, the stage driver 200 rotates the stage about a central rotation axis thereof. Accordingly, the sliced specimen SP2 is rotated , and is cut into a disc shape by the laser beam LB to form the punched specimen SP3. The punched specimen SP3 may have a diameter of about 3 mm. In addition, the laser unit 300 may inject the etching gas EG to the laser beam emitted region of the sliced specimen SP2 to accelerate the processing using the laser beam LB.

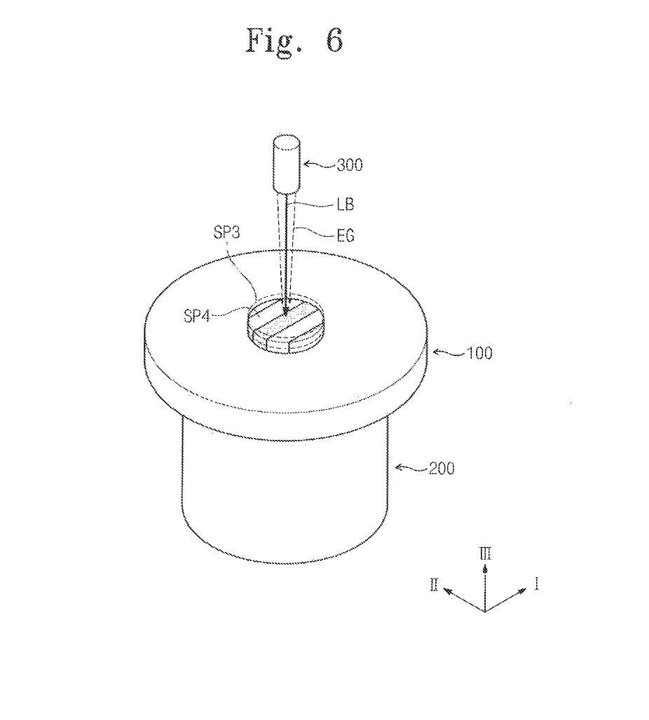

FIG. 6 shows the grinding process applied to the punched specimen SP3. Referring to FIG. 6, a portion of the sliced specimen SP2 excluding the punched specimen SP3 is removed from the stage by the operator or the robot (not shown). The punched specimen SP3 is moved to the initial processing position by the horizontal movement of the stage 100. The laser unit 300 emits the laser beam LB vertically downward to the punched specimen SP3. The punched specimen SP3 is linearly moved in the first and second directions and II according to the movement of the stage 100. As a result, an upper surface of the punched specimen SP3 is ground by the laser beam LB emitted by the laser unit 300. The laser unit 300 may inject the etching gas to the laser beam emitted region of the punched specimen SP3 to accelerate the processing using the laser beam LB. Next, the punched specimen SP3 is flipped by the operator or the robot (not shown) and placed on the stage 100. A lower surface of the punched specimen SP3 is now ground in the same manner as the upper surface. The ground specimen SP4 of which both surfaces are ground may have a thickness of about 100 μm.

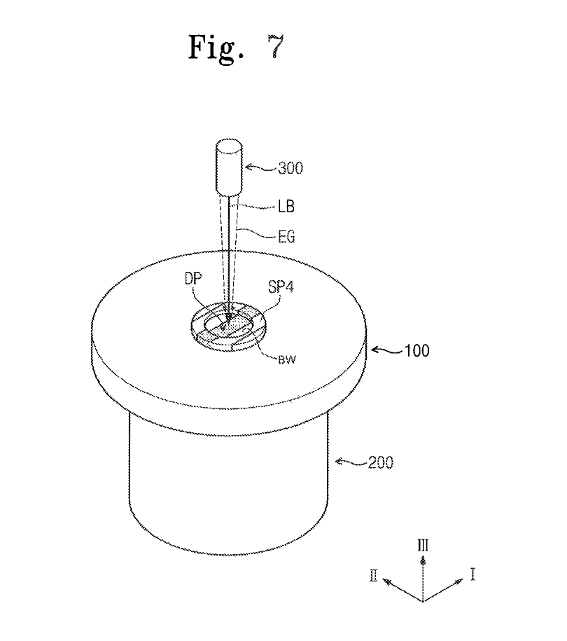

FIG. 7 shows the dimpling process of the ground specimen SP4. Referring to FIGS. 2, 6, and 7, the ground specimen SP4 is moved to the initial processing position by the horizontal movement of the stage 100. The laser unit 300 emits the laser beam LB vertically downward to the ground specimen SP4 while the ground specimen SP4 is linearly moved in the first and second directions I and II by the movement of the stage 100. Accordingly, the dimple DP having a recessed form is formed on an upper surface of the ground specimen SP4 by the laser beam LB emitted by the laser unit 300. Further, an inner circumferential wall 50 extends from the bottom wall BW and surrounds the dimple DP. During the processing, the thickness of the bottom wall BW of the dimple DP is measured by the thickness measuring unit 400. The dimpling process is performed until the thickness of the dimpled specimen SP5 reaches about 1 μm. In addition, the laser unit 300 may inject the etching gas EG to accelerate the processing using the laser beam LB.

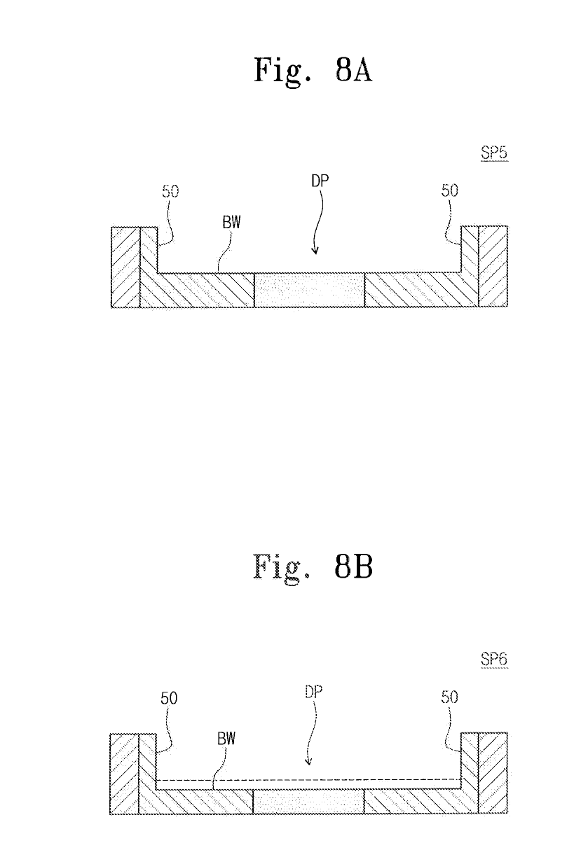

FIG. 8A is a cross sectional view of the dimpled specimen and FIG. 8B is a cross sectional view of the final specimen to be analyzed. Referring to FIGS. 8A and 8B, a dimpled specimen SP5 undergoes a miffing process, i.e., milling, thereby becoming the final analysis specimen SP6 shown in FIG. 8B. Since the milling is performed in a similar manner as the dimpling shown in FIG. 7, a detailed description thereof will be omitted. However, the intensity of the laser beam LB used in the milling process may be less than the intensity of the laser beam LB used in the dimpling process since the milling is a more precise surface process to remove thin and fine scratches from the bottom wall BW of the dimple DP. After the milling procedure, a portion of the bottom wall BW is etched away, as shown by the dashed line in FIG. 8B. Accordingly, the dimple DP may be formed having a thickness of about 0.5 to 1 at the bottom wall BW in the final analysis specimen SP6, as shown in FIG. 8B.

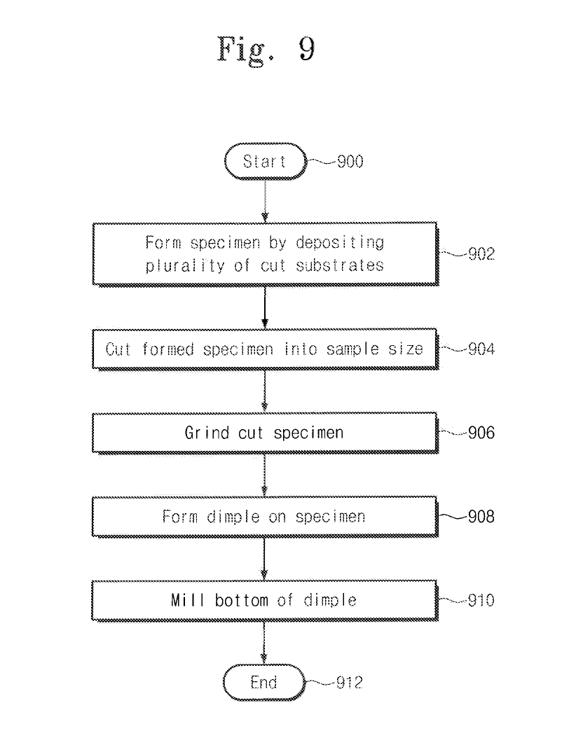

Referring now to FIG. 9, a flowchart illustrates an exemplary specimen processing method according to the present general inventive concept. The method begins at operation 900 and proceeds to operation 902 to form an initial specimen by depositing a plurality of cut substrates together. The plurality of cut substrates may include at least one semiconductor substrate and at least one dummy substrate. In operation 904, the formed specimen is cut into a sample size. For example, the formed specimen may be sliced to produce the sliced specimen SP2. In operation 906, the cut specimen is grinded to produce a ground specimen, such as, for example, specimen SP4. Additionally, both sides of the cut specimen may be grinded. A dimple is formed on at least one side of the grinded specimen to form, for example, a dimpled specimen SP5 in operation 908. In operation 910, the bottom of the dimpled specimen is milled to remove thin and fine scratches from the bottom of the dimple DP. Accordingly, a final specimen to be analyzed in formed at operation 910, and the method ends at operation 912.

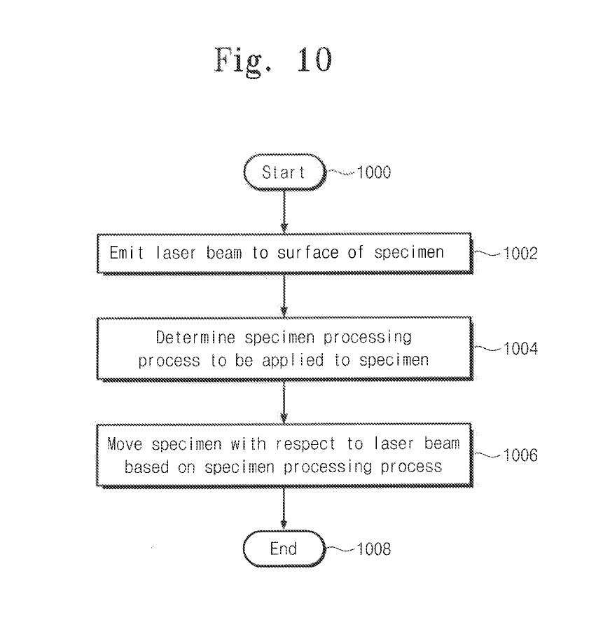

Referring now to FIG. 10, a flowchart illustrates an exemplary method of forming a specimen to be analyzed according to the present general inventive concept. The method begins at operation 1000, and proceeds to operation 1002 where a laser beam is emitted to a surface of a specimen to execute a specimen processing process. The specimen processing process includes at least one of slicing, punching, grinding, dimpling and milling the specimen. At operation 1004, the specimen processing process to be applied to the specimen is determined. At operation 1006, the specimen is moved horizontally and/or vertically, and/or is rotated with respect to the laser beam according to the determined specimen processing process, and the method ends at operation 1008.

As described above, the specimen processing apparatus 10 is capable of manufacturing a final analysis specimen by sequentially performing specimen processing processes using a laser beam with respect to an initial laminate specimen loaded on a stage. As a result, the final specimen manufacturing time may be reduced and the quality of the final specimen may be improved.

According to the embodiment of the general inventive concept, a dimple-shape specimen wherein a plurality of substrates are laminated may be processed by a laser beam.

In addition, a specimen processing time may be reduced while a specimen quality is improved.

Although a few embodiments of the present invention have been shown and described, it would be appreciated by those skilled in the art that changes may be made in these embodiments without departing from the principles and spirit of the general inventive concept, the scope of which is defined in the claims and their equivalents.

1-9. (canceled)

10. A specimen processing method comprising:
forming a specimen by depositing a plurality of cut substrates;
cutting the formed specimen into a sample size and grinding the cut specimen;
forming a dimple on the specimen; and
milling a bottom wall of the dimple,
wherein at least one of the cutting and dimple forming and milling operations are performed by emitting a laser beam to the specimen.

11. The specimen processing method of claim 10, wherein the at least one of the cutting and dimple forming and milling operations are performed while an etching gas is supplied to a laser beam emitted region of the specimen.

12. The specimen processing method of claim 10, wherein at least one of the cutting and dimple forming and milling operations are performed while the specimen is moved relative to a position emitting the laser beam.

13. The specimen processing method of claim 10, wherein the dimple forming and milling operations are performed while a thickness of the bottom wall of the dimple is measured by detecting a wavelength of a reflected light of a light emitted to the bottom wall of the dimple.

14. The specimen processing method of claim 13, wherein the light comprises a laser beam.

15. The specimen processing method of claim 10, wherein intensity of the laser beam used in the milling operation is smaller than intensity of the laser beam used in the dimple forming operation,

16. The specimen processing method of claim 10, wherein the preparing operation comprises:
cutting a semiconductor substrate formed with patterns and a dummy substrate respectively into a rectangular shape by the laser beam; and
depositing and bonding the cut dummy substrate to upper and lower parts of the cut semiconductor substrate.

17. The specimen processing method of claim 10, wherein the cutting operation comprises:
firstly cutting the specimen in a deposition direction;
secondly cutting the first-cut specimen into a disc shape; and
grinding both sides of the second-cut specimen,
wherein the first cutting, second cutting, and grinding are performed by emitting the laser beam to the specimen.

18-21. (canceled)

22. A specimen processing method to form a final specimen to be analyzed from a substrate specimen supported by a stage, the method comprising:
emitting a laser beam to a surface of the substrate specimen in response to a supplied power;
determining at least one specimen processing process to be applied to the substrate specimen among a plurality of specimen processing process that change the shape of the substrate specimen; and
moving the specimen with respect to the laser beam based on the determined at least one specimen processing process to change a shape of the substrate specimen to form the final specimen.

23. The specimen processing method of claim 22, further comprising:
controlling an intensity of the laser beam based on the determined at least one specimen processing process,

24. A specimen processing method comprising:
forming an initial substrate specimen including a substrate layer and a dummy layer;
emitting a laser beam to the initial substrate specimen; and
moving the initial substrate specimen with respect to the laser beam according to a plurality of specimen processing procedures that are sequentially executed to form a final specimen to be analyzed.

25. The specimen processing method of claim 24, wherein the moving operation includes moving the initial substrate specimen in a first processing direction during a first specimen processing procedure and moving the initial substrate specimen in a second direction during a second specimen processing procedure and moving the initial substrate specimen in a third processing direction during a third specimen processing procedure.

26. The specimen processing method of claim 25, wherein the first and second and third processing directions are different from one another.
